(19) United States
(12) Patent Application Publication
(10) Pub. No.: US 2005/0277284 A1
(43) Pub. Date: Dec. 15, 2005

(54) Method for manufacturing a semiconductor device

(75) Inventor: Tomoyuki Iguchi, Kanagawa (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/118,369

(22) Filed: May 2, 2005

(30) Foreign Application Priority Data
May 10, 2004 (JP) 2004-139639

(51) Int. Cl. H01L 21/4763; H01L 21/44

(52) U.S. Cl. 438/619

(57) ABSTRACT

A method for manufacturing a semiconductor device includes forming first wirings assigned in a first region and second wirings assigned in a second region having a lower wiring density than the first region; covering the first and second wirings with a sacrificial film; reducing a thickness of the sacrificial film until surfaces of the first and second wirings expose; selectively removing the sacrificial film in the second region; depositing a first insulating film on the first and second wirings; and removing the sacrificial film in the first region, so as to form an air gap between the first wirings below the first insulating film.

### CROSS REFERENCE TO RELATED APPLICATIONS AND INCORPORATION BY REFERENCE

This application is based upon and claims the benefit of priority from prior Japanese patent application P2004-139639 filed on May 10, 2004; the entire contents of which are incorporated by reference herein.

### BACKGROUND OF THE INVENTION

1. Field of the Invention

The present invention relates to a method for manufacturing a semiconductor device for reducing parasitic capacitance between wiring formed in an insulating film on a semiconductor substrate.

2. Description of the Related Art

Semiconductor devices such as a discrete device, a large scale integrated circuit (LSI), have become further miniaturized. The degree of integration of an LSI is continuously increasing. When such a high degree of integration of the LSI is provided, a wiring pitch of a plurality of wires formed on an insulating film on a semiconductor substrate becomes finer. Moreover, a multilevel wiring structure having a plurality of levels of wiring between insulating films on a semiconductor substrate is commonly used in a semiconductor device.

In the manufacturing technology of such a semiconductor device, the development of a low dielectric constant film which is an insulating film having a relative dielectric constant (εᵣ) less than a value εᵣ of silicon dioxide (SiO₂) has been proposed as a countermeasure to reduce capacitive coupling between adjacent interconnect wiring (cross-talk) in order to achieve a high speed operation primarily in a merged memory and logic semiconductor device. As a method for achieving a low dielectric constant, a technology using an air gap has been developed. Air is the ultimate low dielectric constant material having a relative dielectric constant approximately equal to one.

A semiconductor device using an air gap is disclosed in Japanese Patent Laid-Open No. Hei 8(1996)-306775. In the disclosed semiconductor device, a multilevel wiring structure is formed by a lower wiring layer, an upper wiring layer, and an interlevel insulating film between the lower and upper wiring layers. The interlevel insulating film includes a first insulating film, an air gap formed by removing a second insulating film, and a third insulating film. In order to form the air gap, the first insulating film is deposited on a semiconductor substrate so as to cover the lower wiring layer which includes a plurality of adjacent wires. The second insulating film such as photoresist having a softening property is coated on the first insulating film. The third insulating film is deposited on the second insulating film. Subsequently, the upper wiring layer is formed on the third insulating film. Next, the second insulating film is removed so as to form the air gap. In such a manner described above, the interlevel insulating film having an air gap, in which air serves as an insulator, is formed between the upper and lower wiring layers. By including the air gap in parts of the interlevel insulating film, cross-talk between adjacent wiring may decrease due to the low dielectric constant of air. Furthermore, in Japanese Patent Laid-Open No. Hei 3 (1991)-126247, a structure is described, in which upper and lower wiring layers are supported by a plurality of columns disposed on a lower wiring layer. The columns are used to support an upper wiring layer and to provide an air gap as an interlevel insulator between the upper and lower wiring layers.

Generally, in order to form an air gap, a sacrificial film is formed between a plurality of wiring layers. After depositing an insulating film such as a bridge film or a protective film for the wiring layers, on surfaces of the sacrificial film and the wiring, the sacrificial film is removed by some kind of reaction, so as to form an air gap between the wiring layers. In a portion of the air gap where an area among the wiring is comparatively large, strength of the bridge film is not sufficient. Therefore, the bridge film may collapse and may be removed from the surface of the wirings. Accordingly, a countermeasure to prevent removal of the bridge film is necessary to increase the degree of integration of a semiconductor device.

For example, a sacrificial film such as photoresist is coated on the entire surface of the semiconductor substrate so as to cover a wiring pattern including pads. A thickness of the sacrificial film is reduced by etch back, so as to expose a surface of the wiring pattern. A bridge film such as an insulating film, is deposited on the semiconductor substrate so as to cover the sacrificial film and the wiring pattern. Thereafter, the sacrificial film is removed by etching or the like, so as to form an air gaps between wiring of the wiring pattern. Since an area of the air gap between the adjacent wires in a region of high density wiring, is small, the bridge film may not collapse in this area. However, since an area of the air gap between the pads in a peripheral portion of the region of high density wiring is large, the bridge film may often collapse in this area.

### SUMMARY OF THE INVENTION

A first aspect of the present invention inheres in a method for manufacturing a semiconductor device including forming a plurality of first wirings assigned in a first region and a plurality of second wirings assigned in a second region above a semiconductor substrate, the second region having a lower wiring density than the first region; covering the first and second wirings with a sacrificial film; reducing a thickness of the sacrificial film until surfaces of the first and second wirings expose; selectively removing the sacrificial film in the second region; depositing a first insulating film on the first and second wirings after selectively removing the sacrificial film; and removing the sacrificial film in the first region, so as to form an air gap between the first wirings below the first insulating film.

A second aspect of the present invention inheres in a method for manufacturing a semiconductor device including forming a sacrificial film above a semiconductor substrate; forming a plurality of first patterns assigned in a first region and a plurality of second patterns assigned in a second region by selectively removing the sacrificial film, the second region having a lower pattern density than the first region; depositing a metal film to cover the first and second patterns; forming a plurality of first wirings assigned in the first region and a plurality of second wirings assigned in the second region, by reducing a thickness of the metal film until a surface of the sacrificial film exposes; selectively removing the sacrificial film in the second region after forming the first and second wirings; depositing a first insulating film on the first and second wirings after selectively removing the sacrificial film; and removing the sacrificial film in the first region, so as to form an air gap between the first wirings below the first insulating film.

### BRIEF DESCRIPTION OF THE DRAWINGS

FIG. 1 is a plan view showing an example of a semiconductor device according to a first embodiment of the present invention.

FIG. 2 is a cross section view taken on line II-II of the semiconductor device shown in FIG. 1.

FIGS. 3 through 8 are cross section views showing an example of a manufacturing method of a semiconductor device according to the first embodiment of the present invention.

FIGS. 9 through 11 are cross section views showing another example of a manufacturing method of a semiconductor device according to the first embodiment of the present invention.

FIGS. 12 through 19 are cross section views showing an example of a manufacturing method of a semiconductor device according to a second embodiment of the present invention.

FIG. 20 is a flowchart for explaining an example of a manufacturing method of a semiconductor device according to the second embodiment of the present invention.

FIG. 21 is a cross section view showing an example of a semiconductor device according to a third embodiment of the present invention.

FIG. 22 is a plan view showing an example of a semiconductor device according to other embodiments of the present invention.

FIG. 23 is a cross section view taken on line XXIII-XXIII of the semiconductor device shown in FIG. 22.

### DETAILED DESCRIPTION OF THE INVENTION

Various embodiments of the present invention will be described with reference to the accompanying drawings. It is to be noted that the same or similar reference numerals are applied to the same or similar parts and devices throughout the drawings, and the description of the same or similar parts and devices will be omitted or simplified.

### First Embodiment

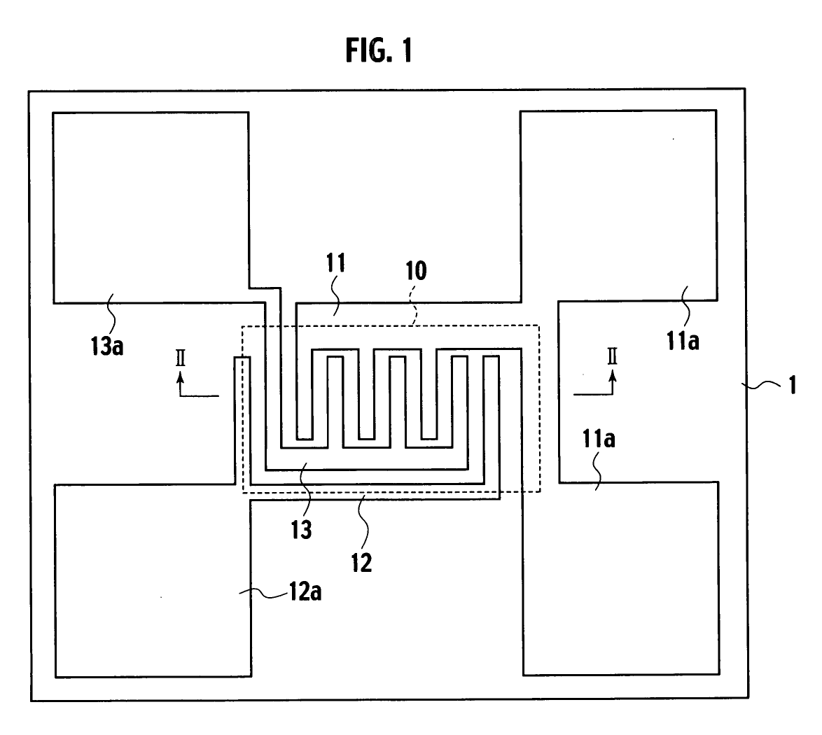

In a first embodiment of the present invention, a discrete semiconductor device will be described as an example of a semiconductor device. In the semiconductor device according to the first embodiment, wiring patterns of an emitter, a collector and a base of a bipolar transistor are formed on a surface of a semiconductor substrate 1, as shown in FIG. 1. The bipolar transistor is formed on the surface of the semiconductor substrate 1 such as a silicon single crystal substrate. The surface of the semiconductor substrate 1 in which the transistor is formed is covered with a passivation film (not shown) such as an insulator. The wiring patterns, for example, aluminum (Al), are formed on the semiconductor substrate 1.

The wiring patterns such as an emitter extraction electrode (pad) 11a, an emitter wiring 11, a collector extraction electrode (pad) 12a, a collector wiring 12, a base extraction electrode (pad) 13a, and a base wiring 13 are disposed. The emitter pad 11a is electrically connected to an emitter region of the transistor. The emitter wiring 11 is electrically connected to the emitter pad 11a. The collector pad 12a is electrically connected to a collector region of the transistor. The collector wiring 12 is electrically connected to the collector pad 12a. The base pad 13a is electrically connected to a base region of the transistor. The base wiring 13 is electrically connected to the base pad 13a.

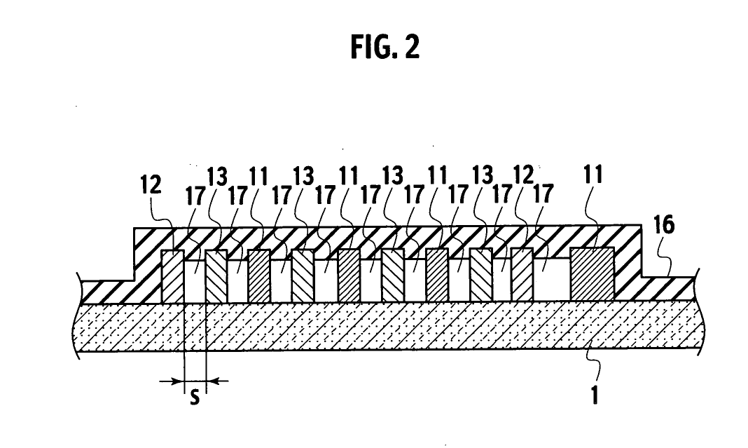

The wiring patterns are divided into a first region and a second region. A plurality of first wirings including the emitter wiring 11, the collector wiring 12, and the base wiring 13, are assigned in the first region. A plurality of second wirings including the emitter pad 11a, the collector pad 12a, and the base pad 13a, are assigned in the second region. The second region has a lower wiring density than the first region. In the first region, a wiring interval S between the adjacent first wirings is as narrow as, for example, about 5 μm or less and capacitive coupling is large. In the second region, the wiring interval S is wide and capacitive coupling is comparatively small. A dividing boundary 10 dividing the first and second regions is provided in a region surrounded by the emitter pad 11a, the collector pad 12a and the base pad 13a. The first region is provided on the inside of the dividing boundary 10. The second region is provided on the outside of the dividing boundary 10. In the first embodiment of the present invention, a bridge film 16 is provided on the first and second wirings, as shown in FIG. 2. An air gap 17 for isolating the first wirings is provided between the first wirings below the bridge film 16. The wiring interval S is desirably about 5 μm or less. When the wiring interval S exceeds 5 μm, the bridge film 16 on the air gap 17 may collapse, and removal of the bridge film 16 may occur. As a result, the manufacturing yield decreases. Here, the length “5 μm” is determined as a reference interval for such collapse with respect to the wiring interval S.

In the first embodiment of the present invention, the air gap 17 is provided in the planar wiring pattern in a single wiring layer. The thickness of an Al wiring of the wiring pattern is about 1 μm. The surface of the Al wiring is protected by an insulating film such as SiO₂ having a thickness of about 0.05 μm, which is not illustrated in FIG. 2. Furthermore, the interval S between the wirings in the high pattern density region in the first embodiment of the present invention is, for example, about 1 μm.

Next, a method for manufacturing a semiconductor device according to the first embodiment of the present invention will be described with reference to FIGS. 3 through 8.

As shown in FIG. 3, wiring patterns including wirings and extraction electrodes, which are connected to an emitter region, a collector region and a base region of a bipolar transistor, are formed on a surface of a semiconductor substrate 1. A passivation film (not shown) such as an insulating film, is formed on the surface of the semiconductor substrate 1. For example, first wirings of the wiring patterns including an emitter wiring 11, a collector wiring 12 and a base wiring 13 are assigned in a first region. Second wirings (not shown) of the wiring patterns including the extraction electrodes are assigned in a second region. A metal film such as Al, is deposited on the entire surface of the semiconductor substrate 1 by chemical vapor deposition (CVD), physical vapor deposition (PVD) and the like. Thereafter, the first and second wirings shown in FIG. 1 are formed by photolithography (photoengraving).

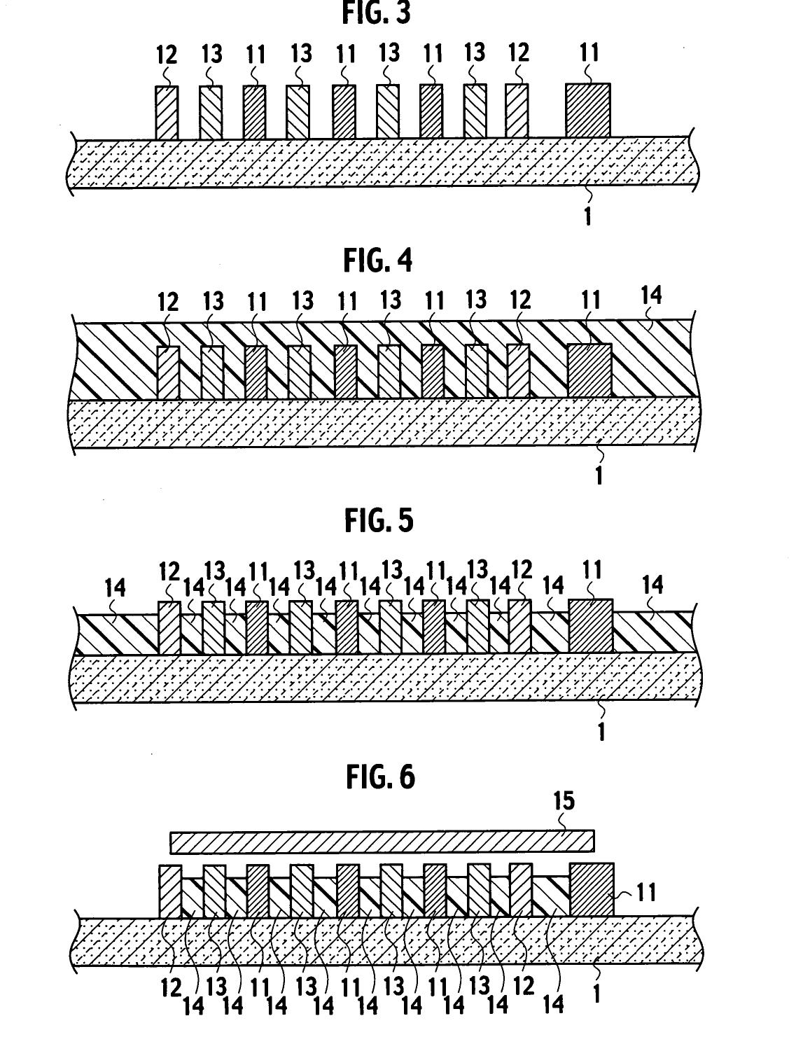

A protection film (not shown) such as SiO₂, is formed on the surface of the metal film. As shown in FIG. 4, a sacrificial film 14 having a thickness of about 1.5 μm is coated on the semiconductor substrate 1 so as to cover the wiring patterns. A photoresist or the like is used for the sacrificial film 14. In the first embodiment of the present invention, a positive type photoresist is used.

As shown in FIG. 5, a thickness of the sacrificial film 14 is reduced to about 0.8 μm by etch back using directional etching such as reactive ion etching (RIE) and the like. As shown in FIG. 6, an opaque portion 15 of a photomask is overlaid on the first region. The sacrificial film 14 is exposed with a light transmitted through the photomask to project the opaque portion 15 on the sacrificial film 14. After development, the sacrificial film 14 in a second region provided on the outside of the first region, is selectively removed. Here, the second region has a lower wiring density than the first region.

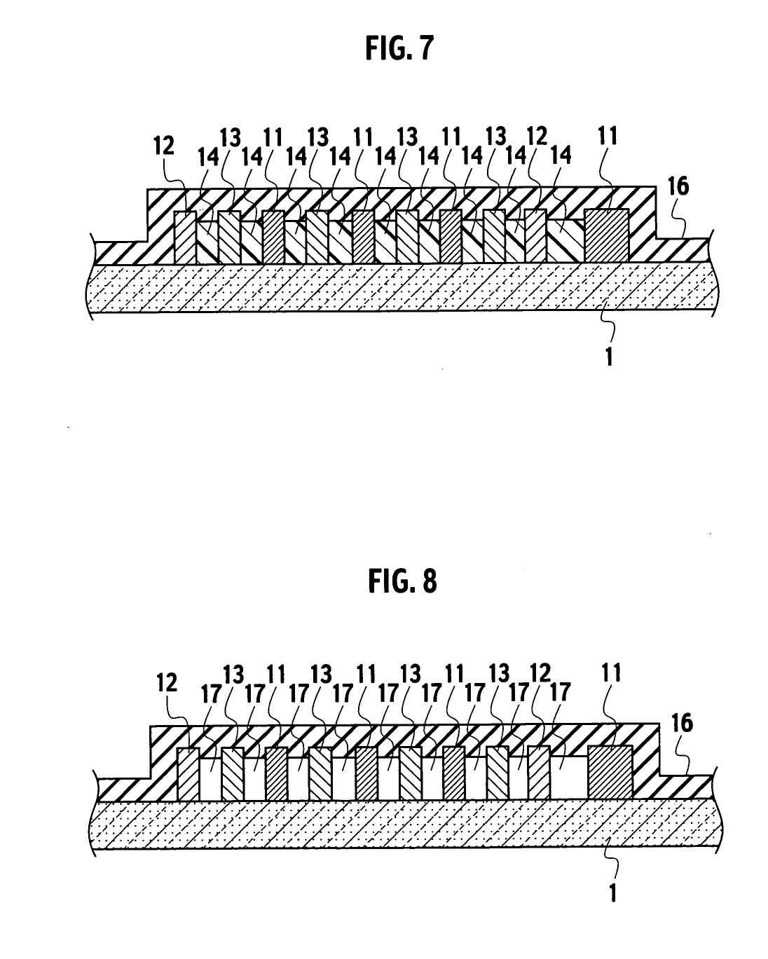

As shown in FIG. 7, a bridge film 16 such as spin on glass (SOG) with a thickness of about 0.5 μm is coated on the semiconductor substrate 1 to cover the wiring patterns and the sacrificial film 14 between the first wirings. A SOG film used as the bridge film 16, which contains SiO₂, on the wiring patterns and the sacrificial film 14 can be planarized with excellent flatness.

As shown in FIG. 8, the sacrificial film 14 formed on the semiconductor substrate 1 is processed with a resist stripper of an alcohol-based organic solvent such as thinner. Since the SOG film used as the bridge film 16 is a porous material, the resist stripper is supplied through pores in the bridge film 16 to dissolve the sacrificial film 14. The sacrificial film 14, which is provided between the semiconductor substrate 1 and the bridge film 16, and between the emitter wiring 11, the collector wiring 12 and the base wiring 13, is dissolved. Thus, an air gap 17 is formed. The air gap 17 is used as an insulator for isolation between the emitter wiring 11, the collector wiring 12 and the base wiring 13. In such a manner, the wiring patterns, in which the emitter wiring 11, the collector wiring 12 and the base wiring 13 are isolated from each other by the air gap 17, are formed on the semiconductor substrate 1.

When the wiring distance between wirings becomes finer due to continued miniaturization of a semiconductor device, capacitive coupling between the wirings increases. Increase of the capacitive coupling produces a negative effect on an operation of a semiconductor device. In a current semiconductor device, the insulating film between wirings essentially contains SiO₂. The SiO₂ film has a high relative dielectric constant of about 3.9. Thus, the capacitive coupling may be higher. On the other hand, in the first embodiment of the present invention, the air gap 17 is used instead of a insulating film such as SiO₂. The relative dielectric constant of the air gap 17 is as low as about one. Therefore, the capacitive coupling may be decreased.

When using the air gap 17, since the bridge film 16 on the air gap 17 may collapse in a region where a wiring density is low and a wiring interval is wide, it is difficult to use the bridge film 16. In the first embodiment of the present invention, the sacrificial film 14 in the second region is removed by photolithography, prior to depositing the bridge film 16. Accordingly, collapse and removal of the bridge film 16 are prevented. Since the sacrificial film 14 is a photoresist film or the like, it is possible to omit a coating process of a photoresist for patterning the sacrificial film 14 and to simplify the photolithography process.

In the above descriptions, after the formation of the wiring patterns, the sacrificial film 14 are coated on the semiconductor substrate 1, to form the air gap 17. However, the wiring patterns may be formed after patterning the sacrificial film 14 coated on the semiconductor substrate 1.

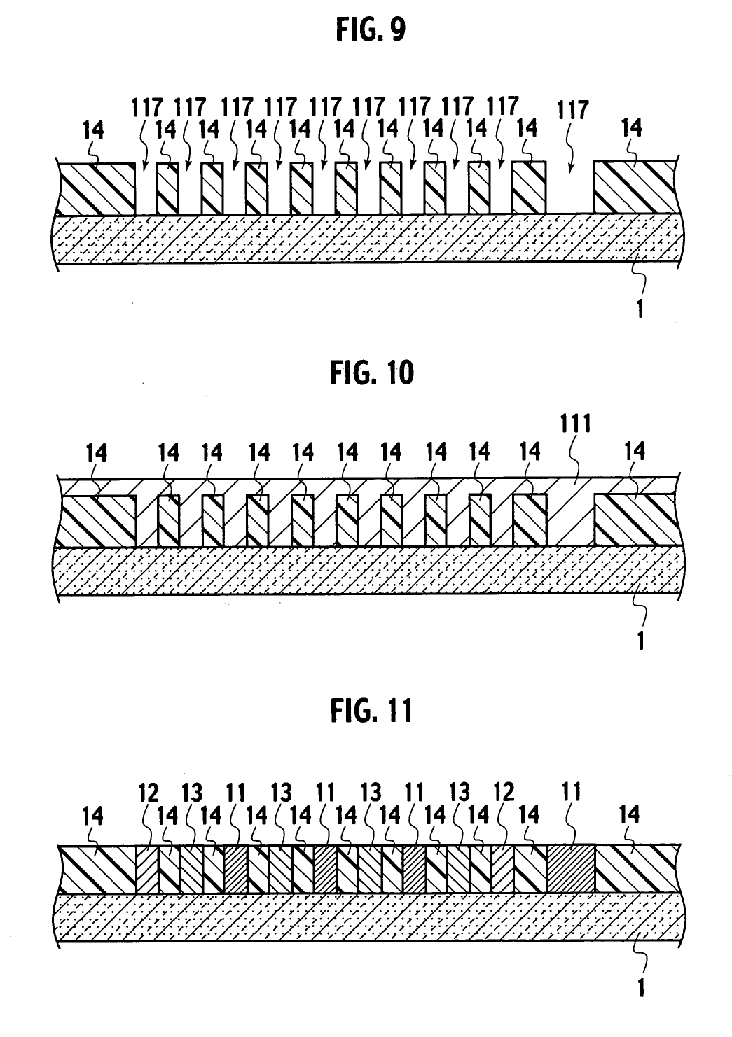

For example, as shown in FIG. 9, a sacrificial film 14 such as a photoresist coated on the semiconductor substrate 1 is selectively removed by photolithography and the like, so as to form first and second patterns in the sacrificial film 14 having opening portions 117. As shown in FIG. 10, a metal film 111 such as Al is deposited by sputtering, CVD and the like, so as to bury the opening portions 117. The sacrificial film 14 is covered by the metal film 111. A thickness of the metal film 111 is reduced by etch back using directional etching such as RIE, so as to expose a surface of the sacrificial film 14. As a result, as shown in FIG. 11, the emitter wiring 11, the collector wiring 12 and the base wiring 13 are respectively formed. Thereafter, the air gap 17 is formed in accordance with the processes shown in FIGS. 6 through 8.

### Second Embodiment

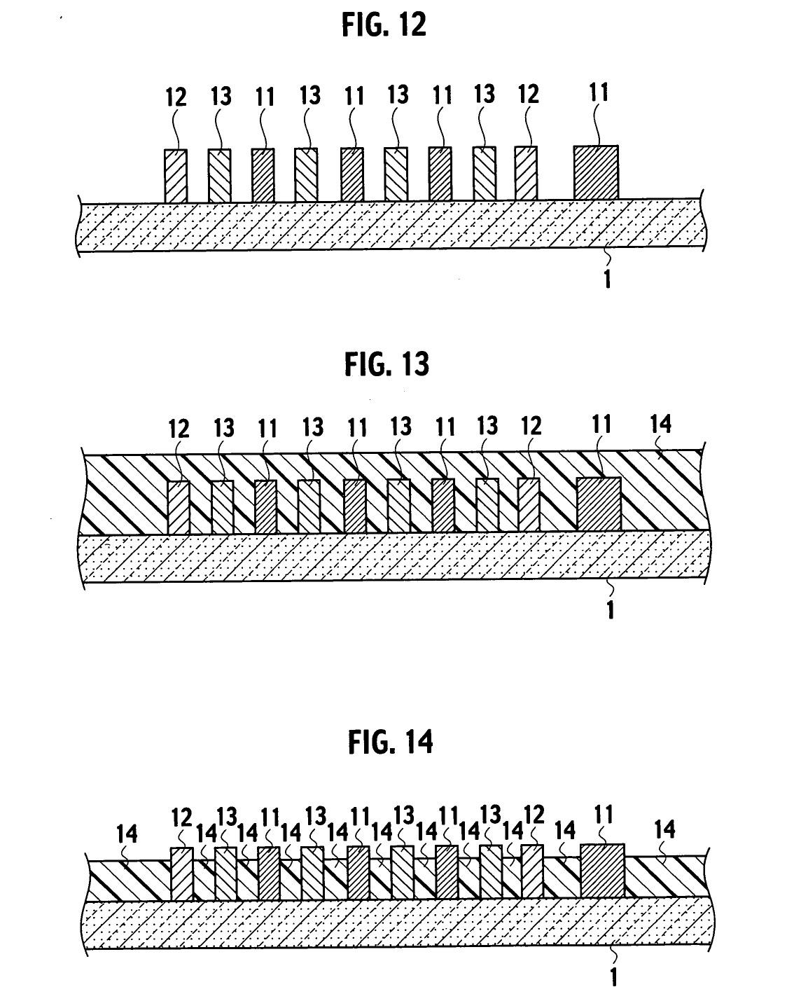

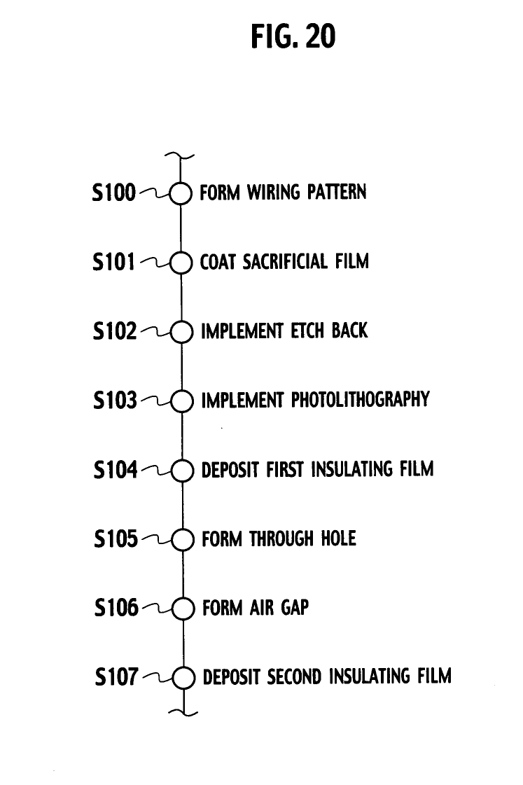

A method for manufacturing a semiconductor device according to a second embodiment of the present invention will be described with FIGS. 12 through 19 showing the cross section views and FIG. 20 showing a process flow. In a semiconductor device according to the second embodiment of the present invention, a bipolar transistor is formed on a semiconductor substrate 1, as shown in FIG. 1. Wiring patterns of the transistor are formed on the surface of the semiconductor substrate 1. The second embodiment of the present invention differs from the first embodiment in that the bridge film includes first and second insulating films, and in that through holes are formed in the first insulating film. Other aspects of the second embodiment of the present invention are identical to the first embodiment. Thus, redundant description will be omitted thereof.

In step S100, wiring patterns including wirings and extraction electrodes, which are connected to an emitter region, a collector region and a base region of a bipolar transistor, are formed on a surface of a semiconductor substrate 1, in common with the first embodiment, as shown in FIG. 12. A passivation film (not shown) such as an insulating film, is formed on the surface of the semiconductor substrate 1. First wirings of the wiring patterns assigned in a first region include an emitter wiring 11, a collector wiring 12 and a base wiring 13. Second wirings (not shown) of the wiring patterns assigned in a second region include the extraction electrodes. A metal film such as Al, is deposited on the entire surface of the semiconductor substrate 1 by CVD, PVD and the like. Thereafter, the wiring patterns shown in FIG. 1 are formed by photolithography. A protection film (not shown) such as SiO₂, is formed on the surface of the metal film with a thickness of about 0.05 μn.

In step S101, a sacrificial film 14 having a thickness of about 1.5 μm is coated on the semiconductor substrate 1 so as to cover the emitter wiring 11, the collector wiring 12 and the base wiring 13, as shown in FIG. 13. A positive type photoresist or the like is used for the sacrificial film 14.

In step S102, a thickness of the sacrificial film 14 is reduced to about 0.8 μm by etch back using directional etching such as reactive ion etching (RIE) and the like, as shown in FIG. 14.

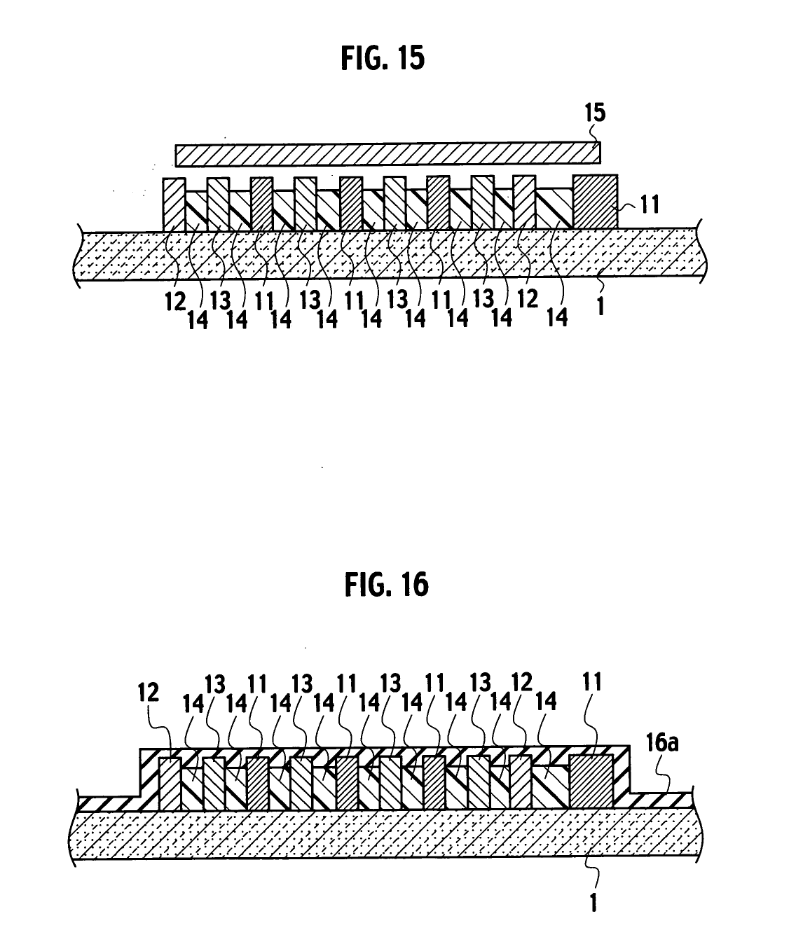

In step S103, an opaque portion 15 of a photomask is overlaid in the first region, as shown in FIG. 15. The opaque portion 15 is projected on the sacrificial film 14. After development, the sacrificial film 14 in a second region provided on the outside of the first region, is removed.

In step S104, a first insulating film 16a with a thickness of about 0.1 μm to about 0.3 μm is deposited on the semiconductor substrate 1 so as to cover the emitter wiring 11, the collector wiring 12, the base wiring 13, and the sacrificial film 14 between the first wirings, as shown in FIG. 16. The first insulating film 16a, such as SiO₂, is deposited by plasma CVD, CVD using tetra-ethoxysilane (TEOS-CVD) and the like.

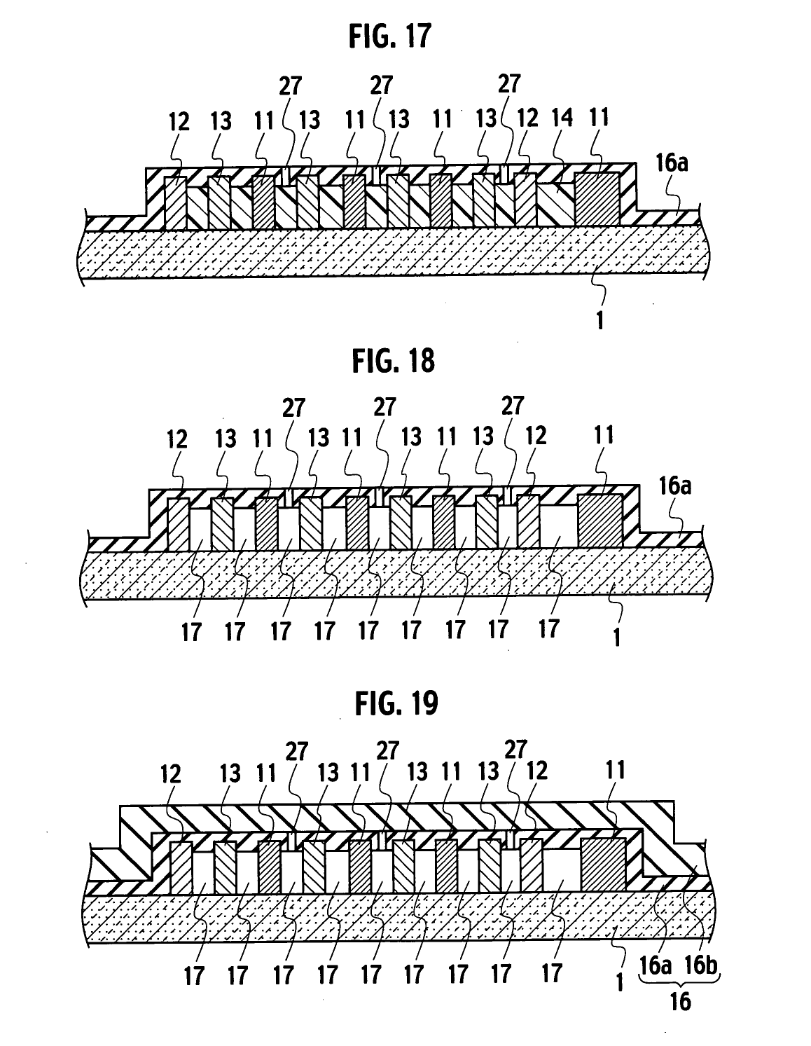

In Step S105, through holes 27 are formed at random positions in the first insulating film 16a as shown in FIG. 17. The positions of the through holes 27 are selected not to expose surfaces of the emitter wiring 11, the collector wiring 12 and the base wiring 13.

In Step S106, a resist stripper of an alcohol-based organic solvent, such as a thinner, is supplied into the sacrificial film 14 from the through holes 27, to dissolve the sacrificial film 14. As shown in FIG. 18, the sacrificial film 14, which is provided between the semiconductor substrate 1 and the bridge film 16, and between the emitter wiring 11, the collector wiring 12 and the base wiring 13, is removed, so as to form an air gap 17. The air gap 17 is used as an insulator for isolating the emitter wiring 11, the collector wiring 12 and the base wiring 13 from each other.

In Step S107, a second insulating film 16b with a thickness of about 0.5 μm is formed on the first insulating film 16a, as shown in FIG. 19. The second insulating film 16b, such as SiO₂, is formed by plasma CVD, TEOS-CVD and the like. Thus, the wiring pattern covered with the bridge film 16 including the first and second insulating films 16a and 16b, in which the emitter wiring 11, the collector wiring 12 and the base wiring 13 are isolated from each other by the air gap 17, is formed on the semiconductor substrate 1.

In the second embodiment of the present invention, the sacrificial film 14 located in a second region having a lower wiring density than the first region is removed by photolithography, prior to forming the air gap 17. Accordingly, collapse and removal of the bridge film 16 is prevented. A photoresist film and the like is used as the sacrificial film 14. Thus, an additional photoresist film is not necessary for photolithography patterning the sacrificial film 14. Therefore, it is possible to simplify the photolithography process. Moreover, in the second embodiment of the present invention, it is possible to effectively remove the sacrificial film 14 of the photoresist, from the through holes 27.

### Third Embodiment

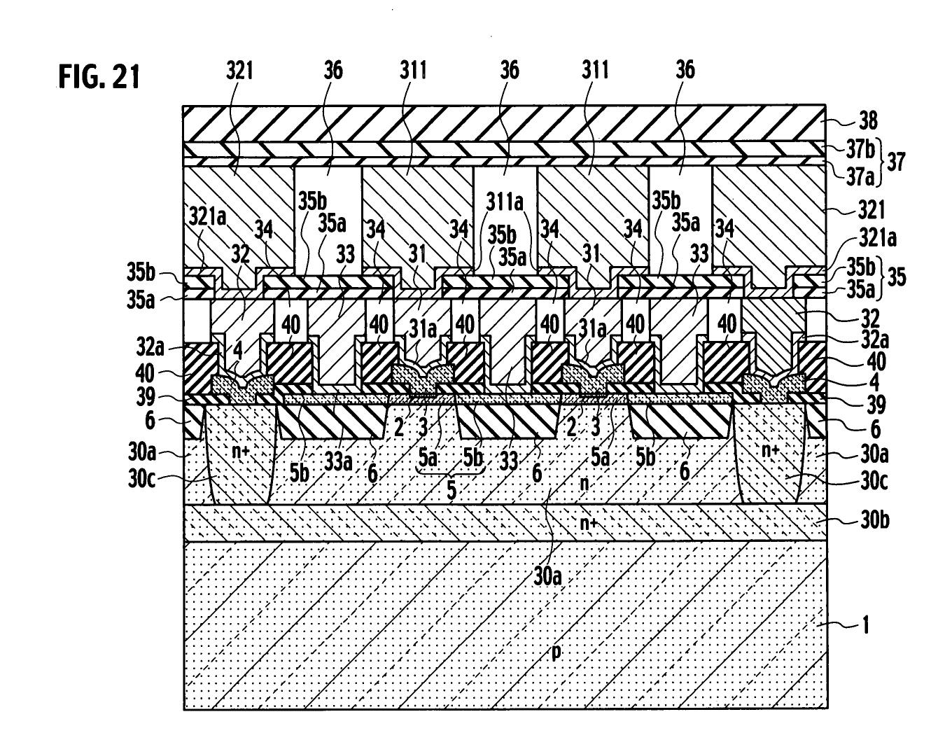

A method for manufacturing a semiconductor device according to a third embodiment of the present invention will be described. In the third embodiment of the present invention, a bipolar transistor is formed on a semiconductor substrate 1, as shown in FIG. 21. Wiring patterns of the transistor are formed on the surface of the semiconductor substrate. In the third embodiment of the present invention, a wiring structure includes two wiring layers. Air gaps 34 and 36 are formed between wirings of the wiring layers in high pattern density regions, respectively.

An n⁺-type buried layer 30b and an n-type epitaxial layer 30a are grown on a semiconductor substrate 1, such as a p-type Si. The bipolar transistor is provided on the epitaxial layer 30a in a region surrounded by the buried layer 30b and an n⁺-type highly-doped region 30c. The highly-doped region 30c extends from a surface of the epitaxial layer 30a to the buried layer 30b. An isolation region 6 such as shallow trench isolation (STI), in which an insulating film such as SiO₂ is buried, is selectively formed in the surface region of the epitaxial layer 30a.

A p-type base region 5 is formed on the epitaxial layer 30a and the isolation region 6 surrounded by the buried layer 30b and the highly-doped region 30c. The base region 5 includes an internal base 5a of single crystal Si on the epitaxial layer 30a and an external base 5b of polycrystalline Si (poly-Si) on the isolation region 6. The surface of the epitaxial layer 30a in which the base region 5 is formed is covered by a passivation film 39 such as SiO₂.

An n-type emitter extraction region 3, such as poly-Si, is formed on the internal base 5a. By diffusing n-type impurities from the emitter extraction region 3, an n-type emitter diffusion region 2 is formed on the surface region of the internal base 5a.

An n-type collector extraction region 4, such as poly-Si, is formed simultaneously with the emitter extraction region 3. The collector extraction region 4 is electrically connected to the highly-doped region 30c. The epitaxial layer 30a surrounded by the highly-doped region 30c serves as a collector region.

An interlevel insulating film 40, such as SiO₂, is formed on the semiconductor substrate 1 in which the bipolar transistor is formed. First wiring patterns are formed on the interlevel insulating film 40 by depositing a metal film, such as Al. The first wiring patterns include a first emitter electrode 31, a first collector electrode 32 and a first base electrode 33.

The first emitter electrode 31 includes a connection plug of tungsten (W) and the like. The first emitter electrode 31 is electrically connected to the emitter extraction region 3 through the connection plug. The connection plug of the first emitter electrode 31 contacts the emitter extraction region 3 through a barrier metal 31a, such as titanium nitride (TiN).

The first collector electrode 32 has a W connection plug and the like. The first collector electrode 32 is electrically connected to the collector extraction region 4 through the connection plug of the first collector electrode 32. The connection plug of the first collector electrode 32 contacts the collector extraction region 4 through a barrier metal 32a such as TiN.

The first base electrode 33 has a W connection plug and the like. The first base electrode 33 is electrically connected to the external base region 5b through the connection plug of the first base electrode 33. The connection plug of the base electrode 33 contacts the external base region 5b through a barrier metal 33a such as TiN.

An air gap 34 and a bridge film 35 are formed in order to isolate the first wiring patterns. A sacrificial film (not shown) is coated on the interlevel insulating film 40 so as to cover the first wiring patterns. A thickness of the sacrificial film is reduced by etch back so as to expose at least surfaces of the first wiring patterns. The sacrificial film in a low pattern density region (second region) is selectively removed by photolithography. The low pattern density region is provided on the outside of a high pattern density region (first region) where the first emitter electrode 31, the first collector electrode 32, and the first base electrode 33 of the first wring pattern are disposed, as well as in a region having no wiring pattern.

Thereafter, A first insulating film 35a, such as SiO₂, is formed by plasma CVD, TEOS-CVD, and the like, so as to cover the first wiring patterns and the sacrificial film. Then, the sacrificial film in the high pattern density region on the interlevel insulating film 40 is removed so as to form the air gap 34 between the first emitter electrode 31, the first collector electrode 32, and the first base electrode 33. A plurality of through holes (not shown) are formed in the first insulating film 35a, the same as in the second embodiment. The through holes are used as an inlet for pouring resist stripper in order to dissolve the sacrificial film.

A second insulating film 35b is deposited on the first insulating film 35a by plasma CVD, TEOSCVD and the like. Thus, the first wiring patterns are covered by the bridge film 35 including the first and second insulating films 35a and 35b on the semiconductor substrate 1. The air gap 34 isolates the first emitter electrode 31, the first collector electrode 32, and the first base electrode 33 from each other.

Second wiring patterns are formed on the bridge film 35 by depositing a metal film, such as Al. The second wiring patterns include a second emitter electrode 311 and a second collector film 321. The second emitter electrode 311 contacts the first emitter electrode 31 through a barrier metal 311a, such as TiN. The second collector electrode 321 contacts the first collector electrode 32 through a barrier metal 321a, such as TiN.

An air gap 36 and a bridge film 37 are formed in order to isolate the second wiring patterns. A sacrificial film (not shown) is formed on the bridge film 35 so as to cover the second wiring patterns. A thickness of the sacrificial film is reduced by etch back so as to expose at least surfaces of the second wiring patterns. The sacrificial film in a low pattern density region is selectively removed by photolithography. The low pattern density region is provided on the outside of a high pattern density region where the second emitter electrode 311 and the second collector electrode 321 are disposed, as well as in a region having no wiring pattern.

A first insulating film 37a, such as SiO₂, is formed by plasma CVD, TEOS-CVD, and the like, so as to cover the second wiring patterns and the sacrificial film. The sacrificial film in the high pattern density region on the bridge film 35 is removed so as to form the air gap 36 between the second emitter electrode 311 and the second collector electrode 321. A plurality of through holes (not shown) are formed in the first insulating film 37a, the same as in the second embodiment. The through holes are used as an inlet for pouring resist stripper in order to dissolve the sacrificial film.

A second insulating film 37b is deposited on the first insulating film 37a by plasma CVD, TEOS-CVD, and the like. Thus, the second wiring patterns are covered by the bridge film 37 including the first and second insulating films 37a and 37b on the semiconductor substrate 1. The air gap 36 isolates the second emitter electrode 311 and the second collector film 321 from each other.

Furthermore, a passivation film 38, such as SiO₂ and silicon nitride (Si₃N₄), is deposited on the bridge film 37. In such a manner described above, the wiring patterns of the semiconductor device is formed.

In the third embodiment of the present invention, the sacrificial film located in the low pattern density region is selectively removed by photolithography. Accordingly, collapse and removal of the bridge films 35 and 37 is prevented. Furthermore, a photoresist film and the like is used as the sacrificial film. Thus, an additional photoresist film is not necessary for photolithography patterning the sacrificial film. Therefore, it is possible to simplify the photolithography process. Moreover, in the third embodiment of the present invention, since an air gap can be arbitrarily provided in a multilevel wiring structure, it is possible to achieve a high degree of integration of a semiconductor device.

### Other Embodiments

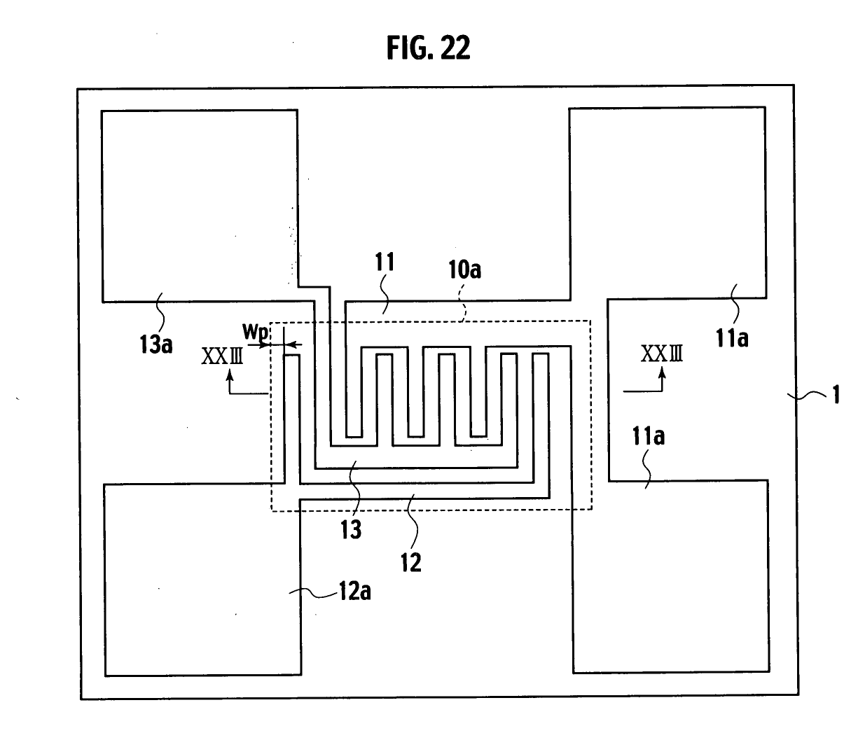

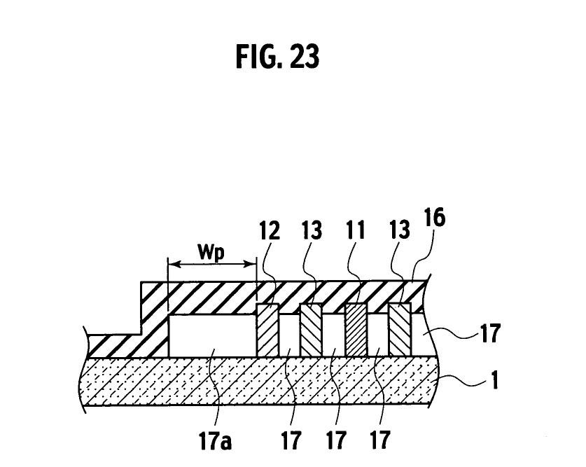

In the first and second embodiments of the present invention, as shown in FIG. 1, the dividing boundary 10 is located on patterns of the emitter wiring 11, the collector wiring 12 and the base wiring 13. However, a dividing boundary is not limited to being located on the patterns. A dividing boundary may extend into a low pattern density region. For example, as shown in FIG. 22, the fine collector wiring 12 is located on the boundary of the first region. A dividing boundary 10a is positioned so as to extend from the collector wiring 12 to the second region by a width Wp. As shown in FIG. 23, the bridge film 16 extends from the outermost pattern of the collector wiring 12 onto the air gap 17a which has the same width Wp corresponding to the dividing boundary 10a. Thus, the air gap 17 is formed within the first region, while the air gap 17a extends from the outermost collector wiring 12 located at the dividing boundary 10a between the first and second regions. In such case, in the photolithography to form the air gaps 17 and 17a, precise alignment for the opaque portion 15 of the photomask shown in FIGS. 6 and 15 with respect to the collector wiring 12 is not required. Thus, the photolithography process to form the air gaps 17 and 17a can be simplified. For the width Wp of the bridge film 16 extending from the dividing boundary 10a to the second region, it is desirable for the width to be not less than about 5 μm corresponding to the reference interval of the wiring interval S, and more desirably not less than about a half the reference interval, for example, not less than about 2.5 μm. When the width Wp exceeds 2.5 μm, the bridge film 16 on the air gap 17a may collapse, so that removal of the bridge film 16 may occur. As a result, the manufacturing yield decreases.

In the first to third embodiments of the present invention, an example in which a discrete semiconductor device is used as a semiconductor device, is described. However, as a semiconductor device, an LSI such as a merged memory and logic semiconductor device may be used. In a chip of the LSI and the like, a plurality of high pattern density regions may be provided. It is possible to easily form an air gap in each of the high pattern density regions.

Various modifications will become possible for those skilled in the art after storing the teachings of the present disclosure without departing from the scope thereof.

1. A method for manufacturing a semiconductor device, comprising:
forming a plurality of first wirings assigned in a first region and a plurality of second wirings assigned in a second region above a semiconductor substrate, the second region having a lower wiring density than the first region;
covering the first and second wirings with a sacrificial film;
reducing a thickness of the sacrificial film until surfaces of the first and second wirings expose;
selectively removing the sacrificial film in the second region;
depositing a first insulating film on the first and second wirings after selectively removing the sacrificial film; and
removing the sacrificial film in the first region, so as to form an air gap between the first wirings below the first insulating film.

2. The method of claim 1, wherein the sacrificial film is a photoresist.

3. The method of claim 1, wherein the first insulating film is spin on glass.

4. The method of claim 1, further comprising: depositing a second insulating film on the first insulating film.

5. The method of claim 1, wherein the air gap is formed within the first region.

6. The method of claim 1, wherein the air gap is formed within the first region and extending from an outermost wiring of the first wirings to the second region, the outermost wiring located at a boundary between the first and second regions.

7. The method of claim 2, wherein selectively removing the sacrificial film in the second region comprises:
overlaying an image of an opaque portion of a photomask above the first region;
exposing the sacrificial film with a light transmitted through the photomask; and
selectively removing an exposed portion of the sacrificial film in the second region by development.

8. The method of claim 3, wherein the sacrificial film is removed by an etchant supplied through the first insulating film.

9. The method of claim 4, wherein, before forming the second insulating film, the sacrificial film is removed by an etchant supplied via a through hole provided in the first insulating film.

10. The method of claim 6, wherein an interval between the first wirings is about 5 μm or less.

11. The method of claim 10, wherein a width of a portion of the air gap extending from the outermost wiring to the second region is about 2.5 μm or less.

12. A method for manufacturing a semiconductor device, comprising:
forming a sacrificial film above a semiconductor substrate;
forming a plurality of first patterns assigned in a first region and a plurality of second patterns assigned in a second region by selectively removing the sacrificial film, the second region having a lower pattern density than the first region;
depositing a metal film to cover the first and second patterns;
forming a plurality of first wirings assigned in the first region and a plurality of second wirings assigned in the second region, by reducing a thickness of the metal film until a surface of the sacrificial film exposes;
selectively removing the sacrificial film in the second region after forming the first and second wirings;
depositing a first insulating film on the first and second wirings after selectively removing the sacrificial film; and
removing the sacrificial film in the first region, so as to form an air gap between the first wirings below the first insulating film.

13. The method of claim 12, wherein the sacrificial film is a photoresist.

14. The method of claim 12, wherein the first insulating film is spin on glass.

15. The method of claim 12, further comprising: depositing a second insulating film on the first insulating film.

16. The method of claim 12, wherein the air gap is formed within the first region.

17. The method of claim 12, wherein the air gap is formed within the first region and extending from an outermost wiring of the first wirings to the second region, the outermost wiring located at a boundary between the first and second regions.

18. The method of claim 13, wherein selectively removing the sacrificial film in the second region comprises:
overlaying an image of an opaque portion of a photomask above the first region;
exposing the sacrificial film with a light transmitted through the photomask; and
selectively removing an exposed portion of the sacrificial film in the second region by development.

19. The method of claim 14, wherein the sacrificial film is removed by an etchant supplied through the first insulating film.

20. The method of claim 15, wherein, before forming the second insulating film, the sacrificial film is removed by an etchant supplied via a through hole provided in the first insulating film.
